(19) United States
(12) Patent Application Publication
(10) Pub. No.: US 2016/0379818 A1
(43) Pub. Date: Dec. 29, 2016

(54) INSULATING A VIA IN A SEMICONDUCTOR SUBSTRATE

(71) Applicant: GLOBALFOUNDRIES Inc., Grand Cayman (KY)

(72) Inventors: CHRISTOPHER COLLINS, WAPPINGERS FALLS, NY (US); MUKTA G. FAROOQ, HOPEWELL JUNCTION, NY (US); YOUBO LIN, RIDGEFIELD, CT (US); JENNIFER A. OAKLEY, POUGHKEEPSIE, NY (US); KEVIN S. PETRARCA, NEWBURGH, NY (US)

(21) Appl. No.: 14/749,750

(22) Filed: Jun. 25, 2015

(51) Int. Cl. H01L 21/02; H01L 23/48; H01L 21/768

(52) U.S. Cl. CPC H01L 21/02271; H01L 21/76898; H01L 23/481

(57) ABSTRACT

Insulating a via in a semiconductor substrate, including: applying a first dielectric layer to the semiconductor substrate; and applying a second dielectric layer to the semiconductor substrate, wherein the second dielectric layer is applied on the first dielectric layer, wherein the second dielectric layer is more conformal than the first dielectric layer.

### BACKGROUND

The present disclosure is generally related to the methods for insulating a thru silicon via in a semiconductor substrate.

### DESCRIPTION OF RELATED ART

Dielectric materials are used to insulate portions of an integrated circuit (‘IC’) during the fabrication process. Some dielectric materials, however, are defined by chemical properties that prevent the dielectric materials from insulating some portions of the IC better than other portions of the IC.

### SUMMARY

Methods and apparatuses for insulating a via in a semiconductor substrate, including: applying a first dielectric layer to the semiconductor substrate; and applying a second dielectric layer to the semiconductor substrate, wherein the second dielectric layer is applied on the first dielectric layer, wherein the second dielectric layer is more conformal that the first dielectric layer.

The foregoing and other objects, features and advantages described herein will be apparent from the following more particular descriptions of example embodiments as illustrated in the accompanying drawings wherein like reference numbers generally represent like parts of example embodiments.

### BRIEF DESCRIPTION OF THE DRAWINGS

FIG. 1 sets forth an illustration of a prior art semiconductor substrate.

FIG. 2 sets forth a flow chart illustrating an example method of insulating a via in a semiconductor substrate according to embodiments of the present disclosure.

FIG. 3 sets forth an illustration of a semiconductor substrate according to embodiments of the present disclosure.

FIG. 4 sets forth an illustration of a semiconductor substrate according to embodiments of the present disclosure.

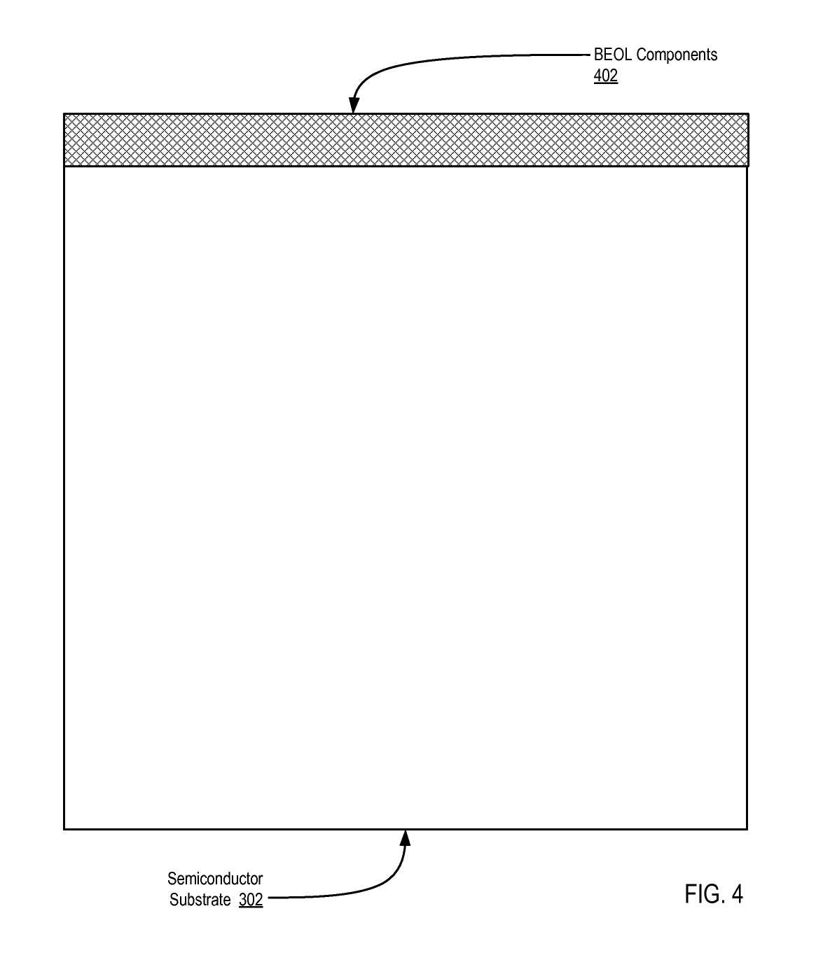

FIG. 5 sets forth an illustration of a semiconductor substrate according to embodiments of the present disclosure.

FIG. 6 sets forth an illustration of a semiconductor substrate according to embodiments of the present disclosure.

FIG. 7 sets forth an illustration of a semiconductor substrate according to embodiments of the present disclosure.

### DETAILED DESCRIPTION OF EXAMPLE EMBODIMENTS

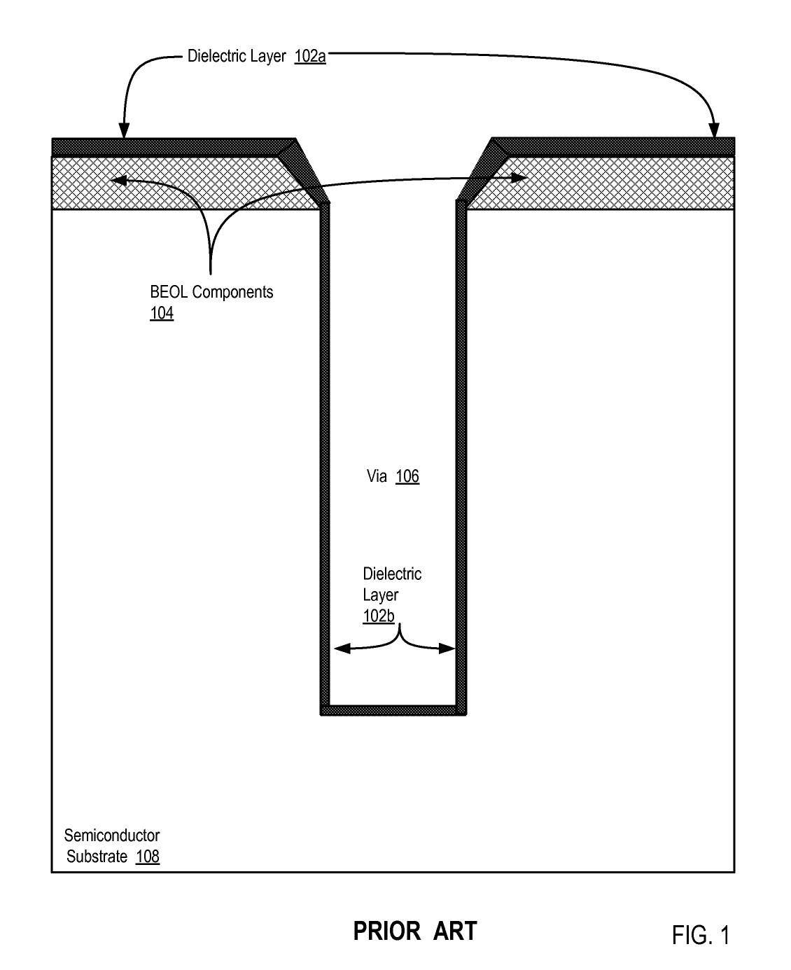

Example methods, apparatus, and products for insulating a via in a semiconductor substrate in accordance with embodiments described herein with reference to the accompanying drawings, beginning with FIG. 1. FIG. 1 sets forth an illustration of a prior art semiconductor substrate (108). The semiconductor substrate (108) includes one or more BEOL components (104) mounted on the semiconductor substrate (108), a via (106) in the semiconductor substrate (108), and a dielectric layer (102a, 102b) applied to the semiconductor substrate (108). The dielectric layer (102a, 102b) applied to the semiconductor substrate (108), however, is not uniform in thickness as the dielectric layer may not be particularly conformal. For example, the portion of the dielectric layer (102a) that is in the field is significantly thicker than the portion of the dielectric layer (102b) that is in the via (106).

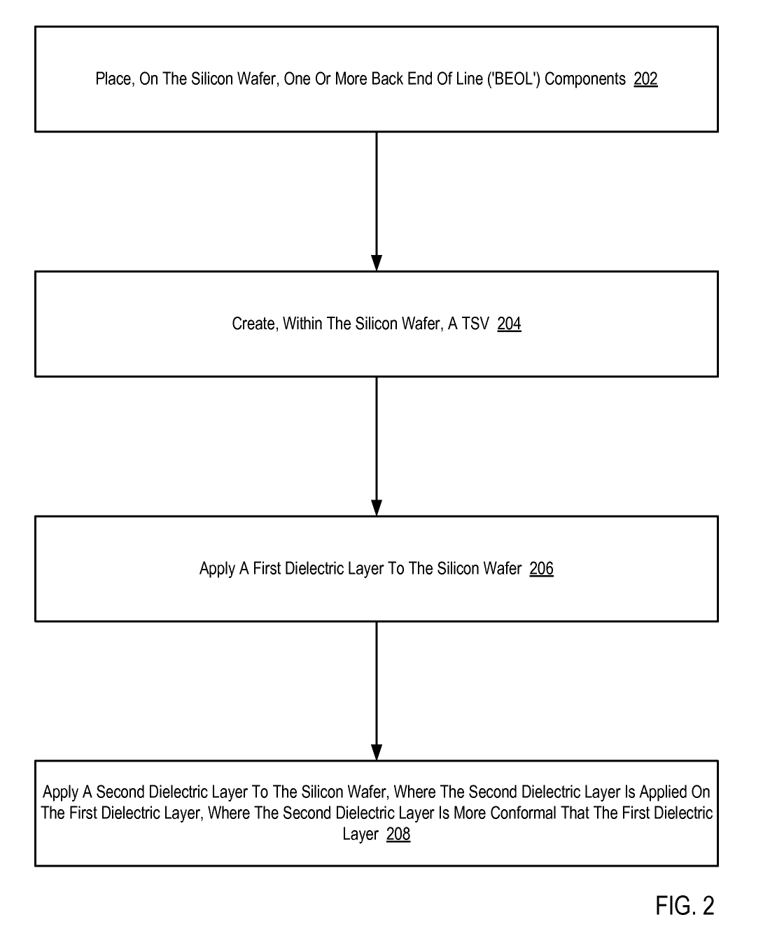

For further explanation, FIG. 2 sets forth a flow chart illustrating an example method of insulating a via in a semiconductor substrate according to embodiments of the present disclosure. A semiconductor substrate may be embodied, for example, as a silicon wafer or other substrate used in electronics for the fabrication of integrated circuits. The via may be embodied as a vertical electrical connection passing completely through semiconductor substrate such as, for example, a through-silicon via (‘TSV’).

The example method depicted in FIG. 2 includes placing (202), on the semiconductor substrate, one or more BEOL components. The back end of line (‘BEOL’) components are those components that may be placed on a semiconductor substrate during the second portion of an integrated-circuit (‘IC’) fabrication process where devices such as transistors, capacitors, resistors, and other devices get interconnected with wiring on the semiconductor substrate. As such, the one or more back end of line (‘BEOL’) components may be embodied, for example, as transistors, capacitors, resistors, contacts, metal levels, bonding sites for chip-to-package connections, and so on. Placing (202) the one or more BEOL components on the semiconductor substrate may be carried out, for example, through the use of one or more specialized fabrication devices in a semiconductor fabrication plant.

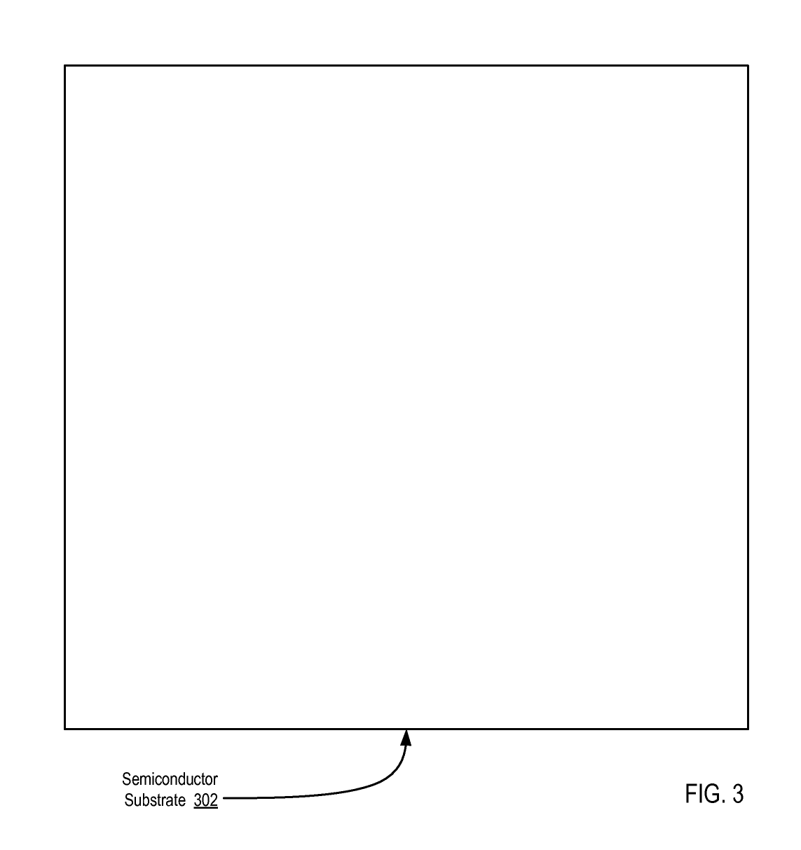

For additional illustration, FIG. 3 sets forth an illustration of a semiconductor substrate (302) according to embodiments of the present disclosure. sets forth an illustration of a semiconductor substrate (302) and BEOL components (402) that have been placed (202) on the semiconductor substrate (302) according to embodiments of the present disclosure.

Referring again to the example depicted in FIG. 2, the example method depicted in FIG. 2 also includes creating (204), within the semiconductor substrate, a thru silicon via. Creating (204) the via within the semiconductor substrate may be carried out, for example, through the use of one or more specialized fabrication devices in a semiconductor fabrication plant. The one or more specialized fabrication devices in the semiconductor fabrication plant may be used to drill the via through the semiconductor substrate.

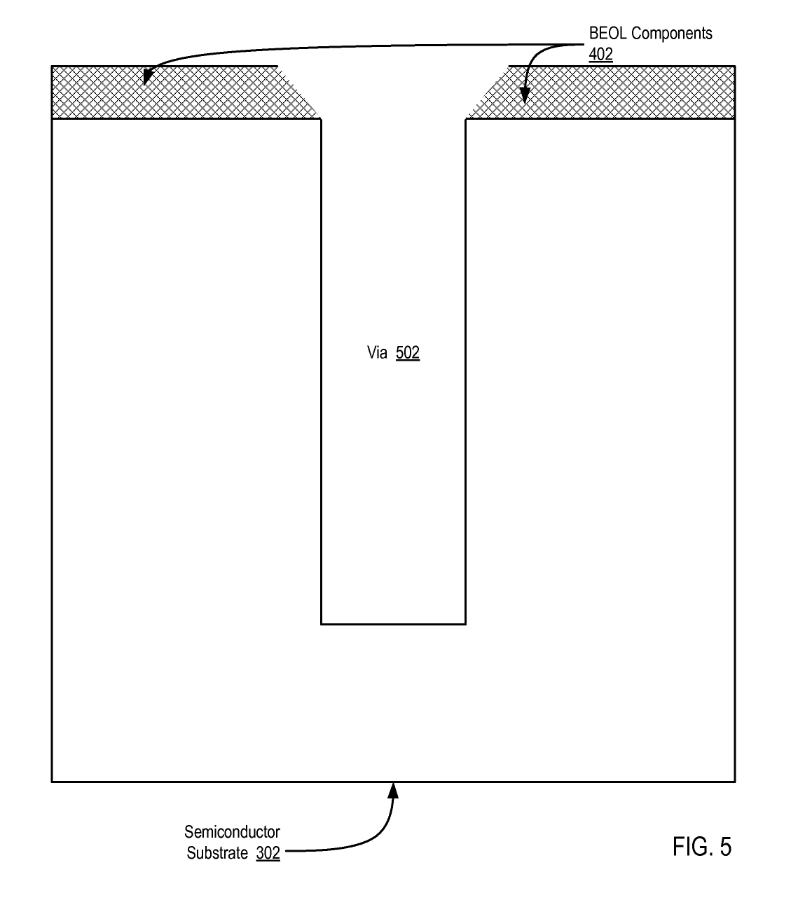

For additional illustration, FIG. 5 sets forth an illustration of a semiconductor substrate (302) and BEOL components (402) that have been placed (202) on the semiconductor substrate (302) according to embodiments of the present disclosure. In the example depicted in FIG. 5, a via (502) has been etched in the semiconductor substrate (302).

Referring again to the example depicted in FIG. 2, the example method depicted in FIG. 2 also includes applying (206) a first dielectric layer to the semiconductor substrate. The first dielectric layer may be embodied, for example, as a chemical vapor deposition (‘CVD’) nitride film. CVD is a chemical process used to produce solid materials. CVD can be used, for example, in the semiconductor industry to produce thin films by exposing the semiconductor substrate to one or more volatile precursors. The one or more volatile precursors can react and/or decompose on the surface of the semiconductor substrate to produce a desired deposit, referred to above as a film. The first dielectric layer applied (206) to the semiconductor substrate is described herein as a CVD nitride film. Such a CVD nitride film may be used as an insulator and chemical barrier in the manufacturing ICs.

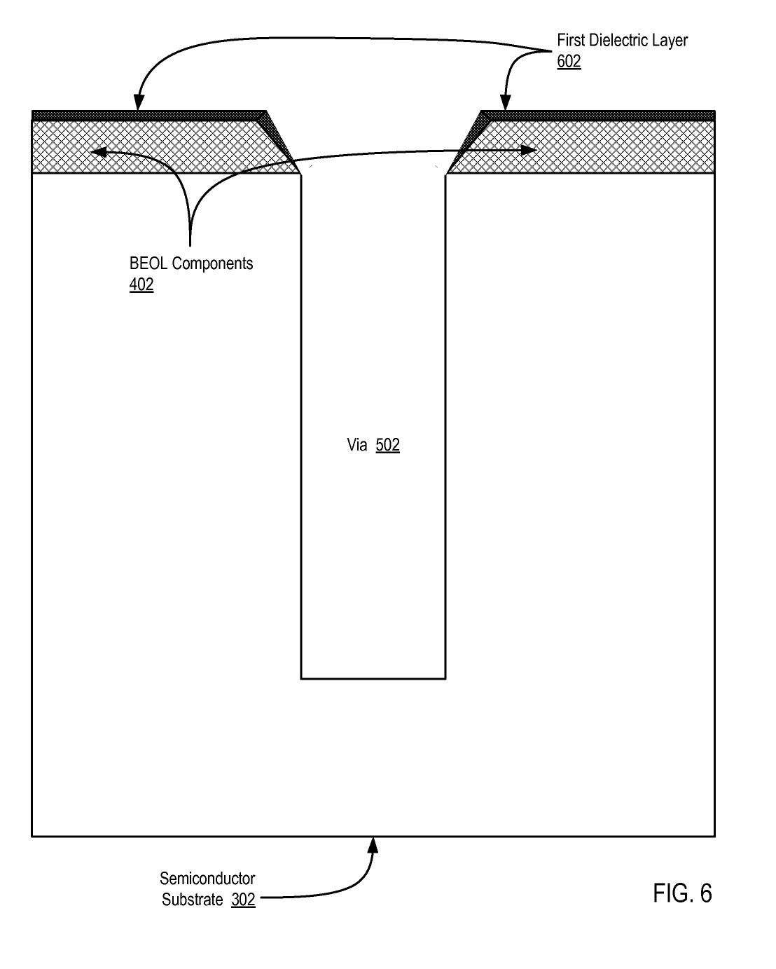

For additional illustration, FIG. 6 sets forth an illustration of a semiconductor substrate (302) and BEOL components (402) that have been placed (202) on the semiconductor substrate (302) according to embodiments of the present disclosure. In the example depicted in FIG. 6, a via (502) also been created (204) in the semiconductor substrate (302) and a first dielectric layer (602) has been applied to the semiconductor substrate (302). The first dielectric layer (602) has been applied to the semiconductor substrate (302) by applying the first dielectric layer (602) on the BEOL components (402) that have been placed (202) on the semiconductor substrate (302). In the example depicted in FIG. 6, because CVD nitride films are not particularly conformal, however, the CVD nitride field is deposited primarily on the field and does not make its way into the via (502).

Referring again to the example depicted in FIG. 2, the example method depicted in FIG. 2 also includes applying (208) a second dielectric layer to the semiconductor substrate. The second dielectric layer may be embodied, for example, as a sub-atmospheric chemical vapor deposition (‘SACVD’) film. An SACVD film may be embodied, for example, as a deposit created using a low-pressure CVD (‘LPCVD’) process where reduced pressures reduce unwanted gas-phase reactions and improve film uniformity as the film is more conformal relative a CVD film. In the example method depicted in FIG. 2, the second dielectric layer is applied on the first dielectric layer and the second dielectric layer is more conformal that the first dielectric layer.

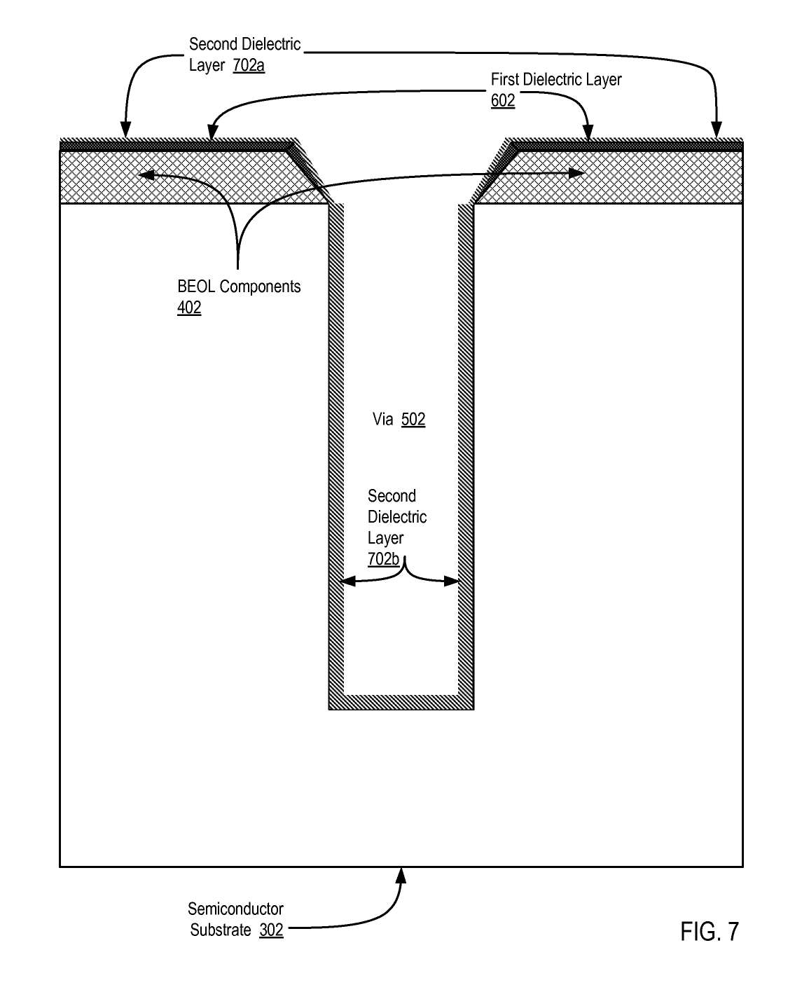

For additional illustration, FIG. 7 sets forth an illustration of a semiconductor substrate (302) and BEOL components (402) that have been placed (202) on the semiconductor substrate (302) according to embodiments of the present disclosure. In the example depicted in FIG. 7, a via (502) also been created (204) in the semiconductor substrate (302) and a first dielectric layer (602) has been applied to the semiconductor substrate (302). The first dielectric layer (602) has been applied to the semiconductor substrate (302) by applying the first dielectric layer (602) on the BEOL components (402) that have been placed (202) on the semiconductor substrate (302). In the example depicted in FIG. 7, the second dielectric layer has also been applied (208) to the semiconductor substrate. Readers will appreciate that because SAVCD grows more quickly on a silicon surface than on a nitride surface, the SAVCD film tends to deposit more heavily on the silicon surfaces (e.g., the via walls) than on the nitride surfaces (e.g., the first dielectric layer). As such, the thickness of (702a) is smaller than the thickness of (102a) of FIG. 1 while the thickness within the via (702b) of FIG. 7 and (102b) of FIG. 1 will remain the same.

It will be understood from the foregoing description that modifications and changes may be made in various embodiments without departing from its true spirit. The descriptions in this specification are for purposes of illustration only and are not to be construed in a limiting sense. The scope of the present disclosure is limited only by the language of the following claims.

What is claimed is:

1. A method of insulating a via in a semiconductor substrate, the method comprising:
applying a first dielectric layer to the semiconductor substrate; and
applying a second dielectric layer to the semiconductor substrate, wherein the second dielectric layer is applied on the first dielectric layer, wherein the second dielectric layer is more conformal that the first dielectric layer.

2. The method of claim 1 wherein the first dielectric layer is a chemical vapor deposition (CVD') nitride film.

3. The method of claim 1 wherein the second dielectric layer is a sub-atmospheric chemical vapor deposition (‘SACVD’) film.

4. The method of claim 1 further comprising:
placing, on the semiconductor substrate, one or more back end of line (‘BEOL’) components; and
creating, within the semiconductor substrate, a via.

5. The method of claim 1 wherein the second dielectric layer grows slower on a CVD nitride film than on a silicon surface.

6. The method of claim 1 wherein the semiconductor substrate is a silicon wafer and the via is a through-silicon via (‘TSV’).

7. A semiconductor substrate, comprising:
one or more back end of line (‘BEOL’) components;
one or more vias;
a first dielectric layer; and
a second dielectric layer, wherein the second dielectric layer is applied on the first dielectric layer, wherein the second dielectric layer is more conformal that the first dielectric layer.

8. The semiconductor substrate of claim 7 wherein the first dielectric layer is a chemical vapor deposition (‘CVD’) nitride film.

9. The semiconductor substrate of claim 7 wherein the second dielectric layer is a sub-atmospheric chemical vapor deposition (‘SACVD’) film.

10. The semiconductor substrate of claim 7 wherein the second dielectric layer conforms less on a CVD nitride film than on a silicon surface.

11. The semiconductor substrate of claim 7 wherein the semiconductor substrate is a silicon wafer and the via is a through-silicon via (‘TSV’).
